(19) United States
(12) Patent Application Publication
(10) Pub. No.: US 2004/0058551 A1
(43) Pub. Date: Mar. 25, 2004

(54) Fluorous cleaning solution for lithographic processing

(76) Inventors: Robert P. Meagley, Beaverton, OR (US); Vani K. Thirumala, San Jose, CA (US); Indrajit Banerjee, San Jose, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/252,305

(22) Filed: Sep. 23, 2002

(51) Int. Cl. H01L 21/302; H01L 21/461

(52) U.S. Cl. 438/710

(57) ABSTRACT

After etching a pattern into a layer of material with a fluorous etch solution, the resulting fluorous post-etch residue is treated with a chemical solution to render the post-etch residue more responsive to polar cleaning solutions. The fluorous post-etch residue, which is normally resistant to removal by polar cleaning solutions, may change its physical and chemical characteristics after being exposed to the chemical solution for a predetermined time and temperature. The residue may then be more easily dissolved and removed with the polar cleaning solution.

### BACKGROUND

1. Technical Field

An embodiment of the invention relates generally to semiconductor fabrication, and in particular relates to a cleaning process used during semiconductor fabrication.

2. Description of the Related Art

During the manufacture of integrated circuits, one procedure involves etching away portions of an exposed layer on the wafer, leaving the remaining portions of the exposed layer in a designated pattern. This process typically involves three operations: 1) The pattern is formed by lithographically creating the pattern in a layer of photoresist (“resist”) material that has been deposited directly above the layer on the substrate to be etched. 2) The photoresist-patterned substrate is then exposed to plasma etch conditions which react with and remove the exposed regions of the target layer (i.e., the portions of target layer not covered with the photoresist pattern). The resist material is comparatively resistant to the plasma and remains substantially in place, so that the areas of the layer to be etched that are directly beneath the resist material remain in place, while the areas not covered by the resist material are etched away. During the plasma etch the resist material is partially degraded and additional material may be deposited as residue from the etch plasma. 3) After etching, the remaining resist material and residues from the etching process are dissolved using a cleaning solution, leaving the designated pattern in the layer that was etched.

Etch plasma frequently employs halogenated species, in particular fluorinated species, to accomplish the selective removal of target layer not covered by resist material. This fluorine-plasma chemistry can impregnate fluorine into the surface of the resist material, and can react with the material being etched to deposit an amorphous fluorinated polymeric material around the margins of the etched regions. If an etched feature (e.g., a via) is sufficiently small, the post-etch residue may substantially fill in the etched feature, and must be removed for subsequent processing (i.e., metallization). Nonpolar polymeric materials, and even more nonpolar fluorous materials, are poorly wetted by the solvents used to formulate conventional cleaning solutions, which are typically polar solutions (typical solvents used in conventional cleaning solutions are water, nmp, amines, etc.). Further, fluorous materials have only limited solubility in such polar systems. Thus the fluorous post-etch residue resists removal because, in part, it is not effectively wetted by, and does not dissolve easily in, conventional cleaning solutions. Extended (extra time) or aggressive (stronger solution and/or higher temperature) cleaning cycles may be used to remove more of the residue, but these tend to damage the etched substrate in areas that are intended to remain intact. This problem limits the minimum feature size that can be reliably produced with a conventional resist/etch/clean procedure and limits the application of certain target layers in the lithographic process.

### BRIEF DESCRIPTION OF THE DRAWINGS

The invention may be understood by referring to the following description and accompanying drawings that are used to illustrate embodiments of the invention. In the drawings:

FIGS. 1A through 1F show a cross section of structures during a fabrication process, according to one embodiment of the invention.

FIG. 2 shows a flowchart of a fabrication process, according to one embodiment of the invention.

### DETAILED DESCRIPTION OF THE INVENTION

In the following description, numerous specific details are set forth. However, it is understood that embodiments of the invention may be practiced without these specific details. In other instances, well-known elements and techniques have not been shown in detail in order not to obscure an understanding of this description.

References to “one embodiment”, “an embodiment”, “example embodiment”, “various embodiments”, etc., indicate that the embodiment(s) of the invention so described may include a particular feature, element, or characteristic, but not every embodiment necessarily includes the particular feature, element, or characteristic. Further, repeated use of the phrase “in one embodiment” does not necessarily refer to the same embodiment, although it may.

In various embodiments, a non-polar chemical solution is used to improve the process of removing resist material and post-etch residue after an etch process in a semiconductor fabrication procedure. Post-etch residue reacts with the non-polar chemical solution to make the residue less resistant to the cleaning process, so that the residue may be effectively removed without resorting to potentially damaging cleaning processes.

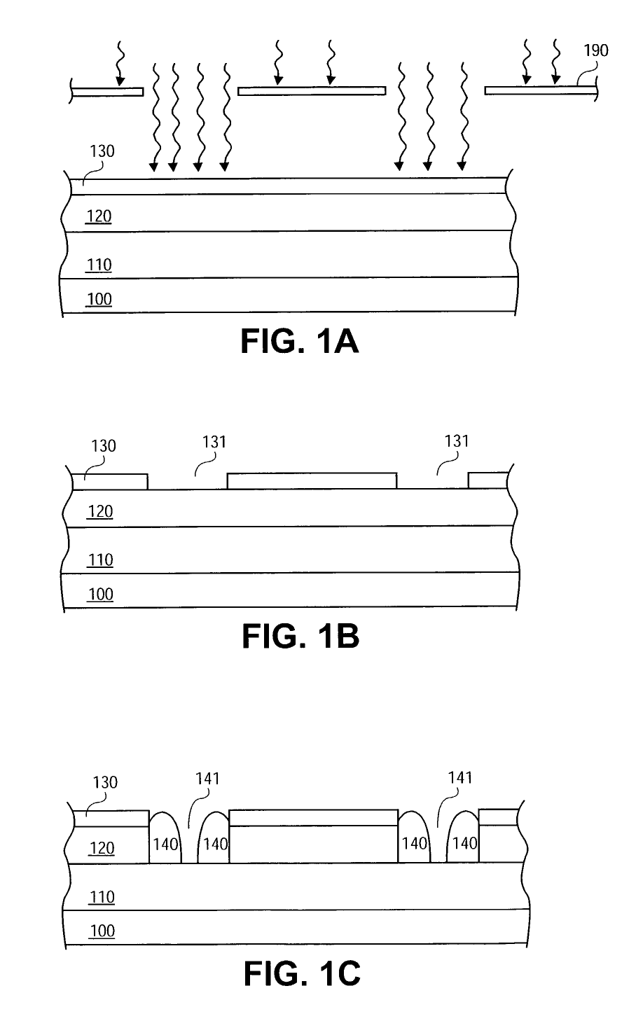

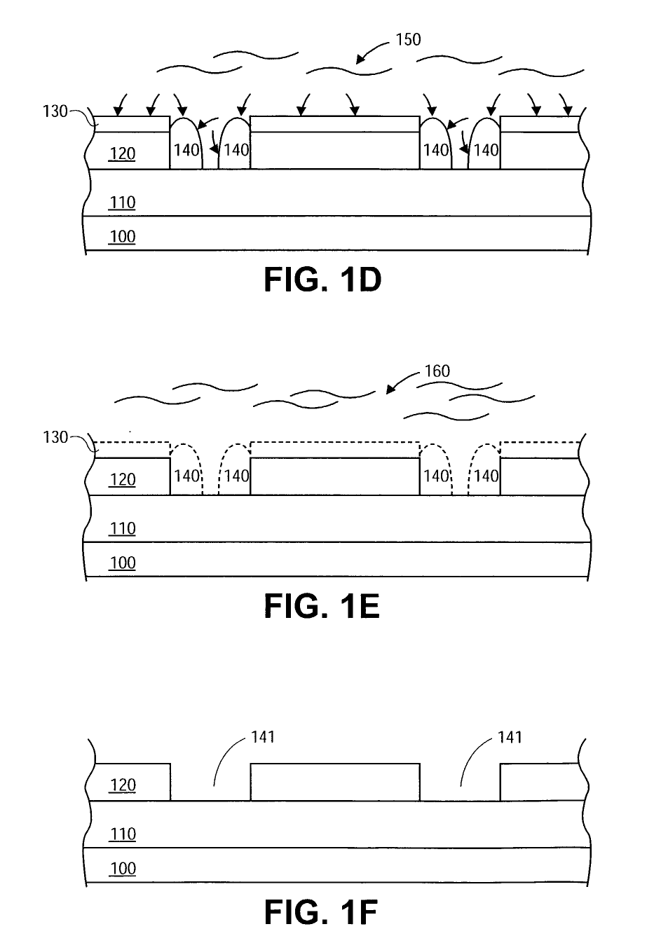

FIGS. 1A through 1F show a cross section of structures during a fabrication process according to one embodiment of the invention. FIGS. 1A through 1F are not drawn to scale, and no inferences should be drawn about relative physical dimensions based on relative dimensions in the drawings.

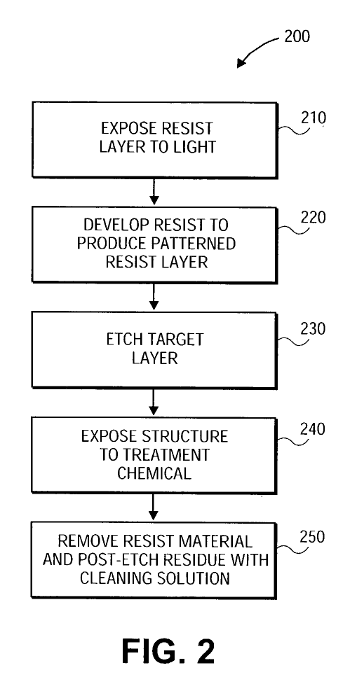

FIG. 2 shows a flowchart of a fabrication process according to one embodiment of the invention. Portions of the following text refer both to FIG. 2 and to FIGS. 1A through 1F; however, it is understood that the structures of FIGS. 1A through 1F and the flowchart 200 of FIG. 2 may be implemented independently of each other. The term “structure”, as used herein, refers collectively to the substrate and all existing layers at the indicated stage in the fabrication process, and to the physical elements in those layers that are being processed together. The term “wafer”, as used herein, refers to a structure containing the substrate and associated layers having multiple copies of a particular design or set of features, with the same process being performed on all copies essentially simultaneously. In one embodiment a wafer has the overall shape of a flat disk between 6 and 12 inches in diameter with features created in the structure on one side of the disk, but other embodiments may have other sizes and/or shapes and/or may have features on both sides.

With reference to FIG. 1A, a specific embodiment with a structure of four layers of semiconductor material is shown, but other embodiments may have other quantities of layers, comprised of various materials. In the embodiment of FIG. 1A, successive layers of material include a resist layer 130, a target layer 120, an intermediate layer 110, and a substrate 100. While in one embodiment resist layer 130 comprises an acrylic polymer, target layer 120 comprises silicon, intermediate layer 110 comprises carbon doped silicon dioxide (CDO), and substrate 100 comprises monocrystalline silicon, other embodiments may use other materials (e.g., resist layer 110 may comprise a fluorinated hydrocarbon, silicon containing aromatic rings containing hydrocarbon, macromolecular, colloidal or molecular resist material, target layer 120 may comprise silicon nitride, intermediate layer 110 may comprise silicon to be subsequently etched using the target layer 120 as a hard mask, etc.).

As used herein, the term “target layer” refers to the material layer to be etched using a pattern developed in the resist layer as an etch mask. The term “resist layer” refers to the layer of material used for lithographically generating the etch mask. The term “substrate” refers to a base material on which the remaining layers are successively disposed, while “intermediate layer” refers to a layer between the substrate and the target layer. These terms are for ease of use in describing the indicated structures and operations, but other terms may be used and/or these terms may be used differently without departing from the scope of various embodiments of the invention.

With reference to FIG. 2, the resist layer is exposed to a pattern of light at block 210. In one embodiment, the pattern of light is created by placing a photo mask between a light source and the resist layer. The photo mask allows portions of the light to strike the resist layer while blocking off other portions. With reference to FIG. 1A, this is illustrated by the two areas of light passing through openings in photo mask 190 and striking resist layer 130. While in one embodiment the openings may be physical holes as indicated, in another embodiment the openings may comprise solid material that is substantially optically transparent to the wavelengths of light being used. In still another embodiment, a reflective photo mask (not shown) may reflect certain areas of light onto resist layer 130, while not reflecting other areas of light. While in one embodiment, an entire wafer may be exposed simultaneously, in another embodiment a repetitive pattern may exposed on the wafer by successively exposing a portion of the wafer, stepping the photo mask to a new position, and repeating the exposure at a new location on the wafer. While in one embodiment the exposure light is substantially monochromatic (e.g., laser light), other embodiments may use light composed of a spectrum of wavelengths. While in one embodiment the wavelength(s) of light used are visible to the human eye, in another embodiment the wavelength(s) of light are not visible (e.g., deep ultraviolet light).

Returning to FIG. 2, at block 220 the layer of resist material is developed to reproduce the exposure pattern in the resist layer. Areas of resist material undergo a physical and/or chemical change when exposed to the light so that the development process removes the portions of the resist layer corresponding to the exposure pattern. In one operation using positive photoresist, the exposed areas of resist material are removed by the development process, while in another operation using negative photoresist, the non-exposed areas of resist material are removed by the development process. Although the aforementioned exposure may be a step-and-repeat operation, the entire wafer may be developed essentially simultaneously.

Development of the resist layer may take various forms in various embodiments, but in a particular embodiment development includes: 1) treating the structure with a solution of tetramethylammoniumhydroxide and water, 2) centrifugally removing the solution and dissolved materials from the structure, 3) rinsing the structure with deionized water, and 4) spinning the structure until dry.

In one embodiment, standard lithographic techniques are used in blocks 210 and 220, but other embodiments may use non-standard or yet-to-be-developed techniques (e.g., immersion lithography, epl, molecular imprinting, etc.).

FIG. 1B shows the results after the resist layer 130 of FIG. 1A has been exposed and developed. In the illustrated embodiment, holes 131 are produced in resist layer 130 by removing the radiated portions of resist layer 130. With a particular exposure pattern, the holes 131 may correspond to vias that are to be etched into target layer 120 in a subsequent operation. With other exposure patterns, the holes 131 shown in FIG. 1B may have any feasible size, shape and quantity.

Returning to FIG. 2, at block 230 the target layer is etched by exposing the structure to an etch process. The etch chemistry may be selected so that the material of the target layer is removed by the etch process, but the material of the underlying layer is not, thus automatically stopping the etch process at the bottom of the target layer and assuring uniform depth in all etched features. Although various etch chemistries may be used, in one embodiment a fluorine plasma etch chemistry is used to etch away the areas of the target layer that are exposed by holes in the resist layer. The fluorine plasma may include fluorine ions created by introducing an electrical voltage into a gas of a fluorine compound. In various embodiments, the fluorine compound may include, but is not limited to, silicon fluoride (SF₆), nitrogen trifluoride (NF₃), or boron trifluoride (BF₃). In addition to etching the target layer, the etch process may introduce fluorine into the surface of the resist layer, and may react with the material of the resist layer and the material of the target layer to produce a fluorinated polymeric material that remains in the holes of the target layer that were etched by the etch process (e.g., “veils”, “plugs”, etc.).

FIG. 1C shows the structure after the etch process. As seen, holes 141 have been etched through the target layer 120 by the etch process with the approximate shape and size of holes 131 in the resist material. However, the fluorine in the etch chemical and the material of target layer 130 may combine to produce a post-etch residue 140 which may coat the sides of the newly etched holes as shown. Depending on the diameter of the holes and the thickness of the post-etch residue, the post-etch residue 140 may substantially fill the newly etched holes 141. If left intact, this residue may prevent subsequent processes from filling holes 141 with other material (e.g., conductive metal). The fluorine-impregnated top surface of resist layer 130 may also be more resistant than non-impregnated resist material to a subsequent process that is designed to remove resist material 130.

Returning to FIG. 2, at block 240 the structure is exposed to a treatment chemical to change the characteristics of the fluorinated polymer and the fluorinated surface of resist material 130. In one embodiment the treatment chemical is a liquid, but other embodiments may provide the treatment chemical in other forms (e.g., a gas, supercritical fluid, etc.) The change in characteristics includes swelling the polymer (increasing the separation between the polymer strands through the introduction of small molecules around and between the polymer strands), partial dissolution of the polymeric material, modifying the polymer's physical characteristics such as grain size (intrinsic aggregation size within the polymeric material) and void volume (space between molecules in the polymeric material) and reducing the polymer bonding (reducing the cross-lining between the polymer strands) within the fluorinated polymeric material to make the fluorinated polymeric material more easily removable in a subsequent cleaning operation. This is illustrated in FIG. 1D where the structure is immersed in treatment chemical 150, allowing the treatment chemical 150 to permeate the fluorinated polymer 140 and the surface of resist layer 130, thus changing the characteristics of fluorinated polymer 140 and the surface of resist layer 130. While in one embodiment the treatment chemical is a fluorous solution (e.g., hydrofluoroether), other embodiments may use other chemicals. In one embodiment the structure of FIG. 1D is immersed in a liquid form of treatment chemical 150 for 10-20 minutes (e.g., approximately 15 minutes) at a temperature of 30-50 degrees Celsius (° C.) (e.g., approximately 40° C.), but other embodiments may use other times and/or temperatures and/or states of matter (aerosols, gasses, super critical phases, emulsions, etc.). While in one embodiment a passive immersion is used, in another embodiment motion is introduced into the treatment chemical relative to the structure (e.g., through agitation of the structure, through flowing the treatment chemical across the structure, exposure to ultrasound, etc.) While in one embodiment the entire wafer is exposed to the treatment chemical, in other embodiments only portions of the wafer are exposed (e.g., only one side of the wafer, a portion of one side of the wafer, etc.)

Returning to FIG. 2, at block 250 the remaining resist material and the post-etch residue are removed from the structure with a cleaning solution. In one embodiment the structure is washed by the cleaning solution (e.g., by immersing the structure in the cleaning solution and agitating the structure, by running the cleaning solution over the structure, etc.), but other embodiments may use other techniques. Due to treating the fluorinated polymer with the treatment chemical, the fluorinated polymer may now be effectively removed with the cleaning solution, even if the cleaning solution is a polar liquid. Similarly, treating the structure with the treatment chemical may change the characteristics of the fluorine-impregnated surface of the resist material so that the resist material is more easily removed with the cleaning solution. The results are shown in FIG. 1E where the dashed lines represent the areas that were chemically and/or physically altered at block 240 so that they will be removed in the cleaning process of block 250. In one embodiment the cleaning solution 160 of FIG. 1E is a non-fluorous solution (i.e., a solution that does not include a chemical compound with the element fluorine), but in other embodiments the cleaning solution may be a fluorous solution. In one embodiment the cleaning solution includes C₄F₉OCH₃. In a particular embodiment the cleaning solution is Aleg®. In one embodiment, the structure is exposed to the cleaning solution for 15-25 minutes (e.g., for approximately 20 minutes) at a temperature between 50° C. and 60° C. (e.g., at a temperature of 55° C.), but other embodiments may use other times and/or other temperatures. The results of the cleaning process are shown in FIG. 1F where holes 141 have been cleanly produced in target layer 120 while all resist material 130 and post-etch residue 140 has been removed from the structure without significant damage to either target layer 120 or intermediate layer 110.

The described procedures may be employed on etched features of various sizes and shapes, but are of particular value when used on very small features that may become fully or substantially blocked by post-etch residue after the etch process. In a particular operation, the described procedures are applied to substantially round vias that are less than 300 nm (e.g., approximately 250 nm) in diameter, but features with other dimensions may also be treated with the described process.

The foregoing description is intended to be illustrative and not limiting. Variations will occur to those of skill in the art. Those variations are intended to be included in the various embodiments of the invention, which are limited only by the spirit and scope of the appended claims.

What is claimed is:

1. A method, comprising:
etching exposed areas of a layer of material underlying a patterned resist layer; and
treating post-etch residue disposed in the etched areas of the underlying material with a chemical solution that reduces polymer bonding within the post-etch residue.

2. The method of claim 1, wherein:
said treating the post-etch residue comprises treating a fluorinated polymer.

3. The method of claim 1, wherein:
said treating with the chemical solution comprises treating with a fluorous solution.

4. The method of claim 3, wherein:
said treating with the fluorous solution comprises treating with hydrofluoroether.

5. The method of claim 1, wherein:
said treating with the chemical solution comprises immersing in the chemical solution within a temperature range of approximately 30-40 degrees Celsius.

6. The method of claim 1, wherein:
said treating with the chemical solution comprises immersing in the chemical solution for a time within a range of approximately 10-20 minutes.

7. The method of claim 1, wherein:
treating the post-etch residue comprises removing the treated post-etch residue with a cleaning solution.

8. The method of claim 7, wherein:
said removing with the cleaning solution comprises removing with a polar solvent.

9. The method of claim 7, wherein:
said removing with the cleaning solution comprises immersing in the cleaning solution for a time within a range of approximately 15-25 minutes.

10. The method of claim 7, wherein:
said removing with the cleaning solution comprises immersing in the cleaning solution within a temperature range of approximately 50-60 degrees Celsius.

11. An apparatus, comprising:
a semiconductor wafer having multiple copies of a certain structure produced in a semiconductor layer, the multiple copies produced by
applying a resist layer onto the semiconductor layer;
exposing the resist layer to a pattern of light;
developing the resist layer to create the pattern in the resist layer;
etching areas of the semiconductor layer exposed by the patterned resist layer;
treating post-etch residue disposed in the etched areas of the semiconductor layer with a chemical solution to reduce polymer bonding in the post-etch residue; and
removing the resist layer and the treated post-etch residue.

12. The apparatus of claim 11, wherein:
said post-etch residue is a fluorinated polymer.

13. The apparatus of claim 12, wherein:
said treating with a chemical solution comprises treating with a fluorous solution.

14. The apparatus of claim 13, wherein:
said treating with a fluorous solution comprises treating with hydrofluoroether.

15. The apparatus of claim 11, wherein:
said treating with a chemical solution comprises
immersing the wafer in the chemical solution;
agitating the wafer; and
removing the wafer from the chemical solution.

16. The apparatus of claim 11, wherein:
said treating with a chemical solution comprises
flowing the chemical solution over the post-etch residue.

17. A method, comprising:
creating a patterned mask in a resist layer disposed on layer of material underlying the resist layer;
etching exposed areas of the layer of material underlying the resist layer; and
treating post-etch residue disposed in the etched areas of the underlying material with a chemical solution to reduce cross-linkage of the polymer strands in the post-etch residue.

18. The method of claim 17, wherein:
said treating the post-etch residue comprises treating a fluorinated polymer.

19. The method of claim 17, wherein:
said treating with the chemical solution comprises treating with a fluorous solution.

20. The method of claim 19, wherein:
said treating with the fluorous solution comprises treating with hydrofluoroether.

21. The method of claim 17, wherein:
said treating with the chemical solution comprises immersing in the chemical solution within a temperature range of approximately 30-40 degrees Celsius.

22. The method of claim 17, wherein:
said treating with the chemical solution comprises immersing in the chemical solution for a time within a range of approximately 10-20 minutes.

23. The method of claim 17, wherein:
treating the post-etch residue comprises removing the treated post-etch residue with a cleaning solution.

24. The method of claim 23, wherein:
said removing with the cleaning solution comprises removing with a polar solvent.

25. The method of claim 23, wherein:
said removing with the cleaning solution comprises immersing in the cleaning solution for a time within a range of approximately 15-25 minutes.

26. The method of claim 23, wherein:
said removing with the cleaning solution comprises immersing in the cleaning solution at a temperature within a range of approximately 50-60 degrees Celsius.
